(19) United States
(12) Patent Application Publication
(10) Pub. No.: US 2015/0013941 A1
(43) Pub. Date: Jan. 15, 2015

(54) Conduction Cooled Chassis With Embedded Heatpipes

(71) Applicant: Emerson Network Power - Embedded Computing, Inc., Tempe, AZ (US)

(72) Inventors: Suzanne Marye WONG, Tempe, AZ (US); Ross ARMSTRONG, Phoenix, AZ (US)

(21) Appl. No.: 13/938,560

(22) Filed: Jul. 10, 2013

(51) Int. Cl. H05K 7/20

(52) U.S. Cl. CPC H05K 7/20336
USPC 165/104.21

(57) ABSTRACT

An electronics chassis heat-pipe conduction cooling system includes a first chassis wall having multiple heat transfer sleeves defining multiple first chassis slots. A cabinet bottom chassis wall has multiple second chassis slots. A cabinet second chassis wall has multiple heat transfer sleeves defining multiple third chassis slots. Multiple first heat-pipes each have a vertical leg received in one of the first chassis slots and a horizontal leg received in one of the second chassis slots. Multiple second heat-pipes each have a vertical leg received in one of the third chassis slots and a horizontal leg received in one of the second chassis slots. A cold plate in direct contact with the cabinet bottom chassis wall completes a conduction cooling path including the vertical leg of the first and second heat-pipes through the horizontal leg of the first and second heat-pipes and the bottom chassis wall.

### FIELD

The present disclosure relates to heat removal components and systems for electronics chassis.

### BACKGROUND

This section provides background information related to the present disclosure which is not necessarily prior art.

Portable and field operative electronic components/cabinets such as card cages and radio equipment often require the internal components to be sealed from atmospheric contaminants, moisture, dirt and the like. This limits or prevents the use of flow through ventilation to remove equipment generated heat. Known solutions include the use of external cooling fins, finned attachments, block-machined cooling surfaces and the like to remove heat from the internal components of the cabinet by convective/conductive heat transfer through the outer walls of the cabinet, through the fins to the atmosphere.

Limitations of known cooling fin designs include the inability to cover the entire surface area of the cabinet with fins due to mechanical attachment limitations, hot spots occurring within the cabinets or at the heat transfer surfaces where radiant and convective heat transfer between the internal components and the cooling fin connection blocks are located, and the inability to evenly distribute the heat load across the surface of the finned components.

### SUMMARY

This section provides a general summary of the disclosure, and is not a comprehensive disclosure of its full scope or all of its features.

According to several aspects, a heat-pipe conduction cooling system for an electronics chassis includes a first cabinet portion having multiple first chassis slots. A second cabinet portion has multiple second chassis slots. A third cabinet portion has multiple third chassis slots. Multiple first heat-pipes have a first portion received in individual ones of the first chassis slots and a second portion received in individual ones of the second chassis slots. Multiple second heat-pipes have a first portion received in individual ones of the third chassis slots and a second portion received in individual ones of the second chassis slots.

According to other aspects, a heat-pipe conduction cooling system for an electronics chassis includes a first cabinet portion defining a first chassis wall having multiple first chassis slots. A second cabinet portion defining a bottom chassis wall has multiple second chassis slots. A third cabinet portion defining a second chassis wall has multiple third chassis slots. Multiple first heat-pipes are individually received in the first chassis slots and in first ones of the second chassis slots. Multiple second heat-pipes are individually received in the third chassis slots and in second ones of the second chassis slots.

According to still other aspects, a heat-pipe conduction cooling system for an electronics chassis includes a cabinet first wall having multiple heat transfer sleeves defining multiple first chassis slots. A cabinet bottom wall has multiple second chassis slots. Multiple first heat-pipes each have a vertical leg received in one of the first chassis slots and a horizontal leg received one of the second chassis slots.

According to further aspects, an embedded heat-pipe conduction cooling system for an electronics chassis includes a first chassis wall having multiple heat transfer sleeves defining multiple first chassis slots. A cabinet bottom chassis wall has multiple second chassis slots. A cabinet second chassis wall has multiple heat transfer sleeves defining multiple third chassis slots. Multiple first heat-pipes each have a vertical leg received in one of the first chassis slots and a horizontal leg received in one of the second chassis slots. Multiple second heat-pipes each have a vertical leg received in one of the third chassis slots and a horizontal leg received in one of the second chassis slots. A cold plate in direct contact with the cabinet bottom chassis wall completes a conduction heat path including the vertical leg of the first and second heat-pipes through the horizontal leg of the first and second heat-pipes and the bottom chassis wall.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a front right perspective view of a conduction cooled electronics chassis of the present disclosure;

FIG. 2 is a front right perspective view of an interior cavity of the conduction cooled electronics chassis of FIG. 1 having multiple cabinet walls removed for clarity;

FIG. 3 is a front right perspective view modified from FIG. 2 further showing an installed backplane with electronic components mounted thereto; and

FIG. 4 is a front right perspective view modified from FIG. 3 further showing an installed component board.

Corresponding reference numerals indicate corresponding parts throughout the several views of the drawings.

### DETAILED DESCRIPTION

Example embodiments will now be described more fully with reference to the accompanying drawings.

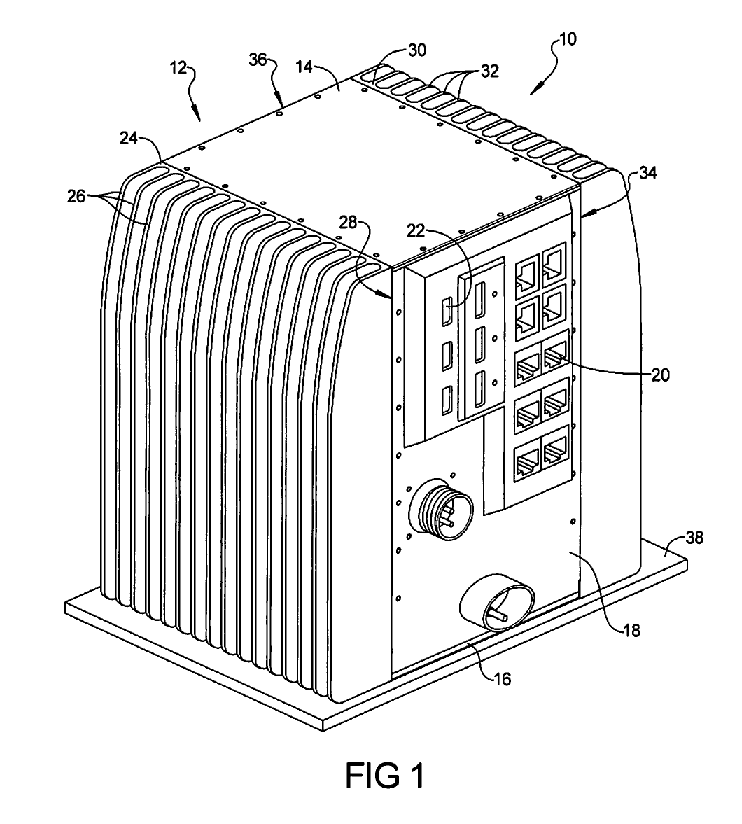

Referring to FIG. 1, a conduction cooled electronics chassis 10 includes a cabinet 12 having an upper wall 14, a bottom wall 16, and a front wall 18. Multiple ports such as COM ports 20 and USB ports 22 can be provided in front wall 18. For conduction/convection cooling cabinet 12 includes a first finned cooling member 24 having multiple parallel cooling fins 26. First finned cooling member 24 is connected such as by fastening to a first side wall 28 of cabinet 12. For conduction/convection cooling cabinet 12 also includes a second finned cooling member 30 having multiple parallel cooling fins 32. Second finned cooling member 30 is connected such as by fastening to a second side wall 34 of cabinet 12. Additional ports such as COM ports 20 and USB ports 22 can also be provided in a rear wall 36 of cabinet 12. Additional conduction cooling of cabinet 12 can also be provided by direct contact between bottom wall 16 and a cold plate 38. Cold plate 38 can also be replaced by any metal mass or object acting to conductively remove heat from the bottom wall 16.

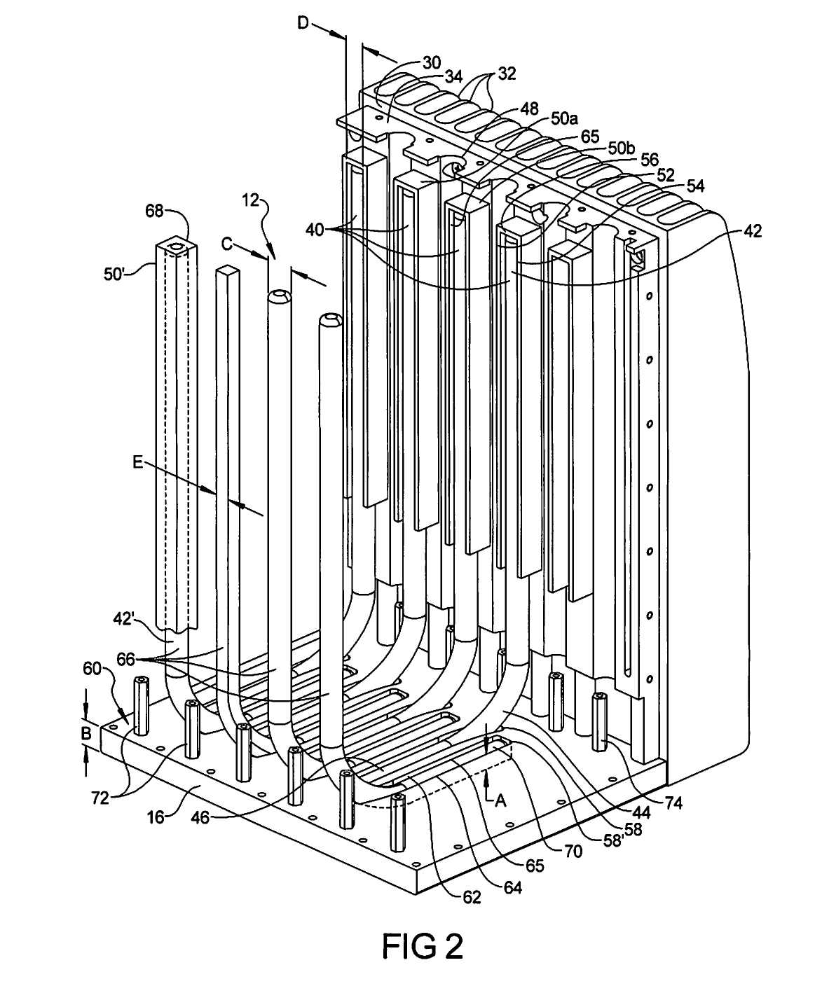

Referring to FIG. 2 and again to FIG. 1, the first side wall 28, the upper wall 14, the front wall 18 and the first finned cooling member 24 are removed for clarity to show an internal cabinet arrangement. Electronics chassis 10 includes multiple L-shaped heat-pipes 40 which directly contact the second side wall 34 to aid cooling fins 32 in conductively transferring heat through second side wall 34. Each heat-pipe 40 includes a vertical leg 42, a bend 44 and a horizontal leg 46. According to several aspects bends 44 are substantially 90 degree bends. Each two vertical legs 42 of successive heat-pipes 40 are oppositely positioned about each of a plurality of component slots 48 created in second side wall 34. Each of the vertical legs 42 are positioned within one of multiple heat transfer sleeves 50. Each heat transfer sleeve 50 includes opposed vertical first and second walls 52, 54 which are in direct contact with the associated vertical leg 42 of each heat-pipe 40. The heat transfer sleeves 50 therefore act to increase a surface area of the vertical legs 42 in contact with second side wall 34. A first chassis slot 56 is created between the first and second walls 52, 54 of each of the heat transfer sleeves 50, 50′ that individually receive the vertical legs 42, thereby defining multiple first chassis slots 56 provided at each of the first and second side walls 28, 34.

The horizontal legs 46 of the heat-pipes 40 are individually positioned in one of multiple cavities or second chassis slots 58 created in bottom wall 16 and extending downwardly into bottom wall 16 from an upward facing surface 60 of bottom wall 16. A depth “A” of each of the second chassis slots 58 is less than a thickness “B” of bottom wall 16. According to several aspects, a diameter “C” of the heat-pipes, including at the horizontal legs 46 is substantially equal to the depth “A” of the second chassis slots 58, permitting substantially all (the total diameter “C”) of each horizontal leg 46 to be received within the second chassis slots 58, without extending above surface 60. Opposed first and second walls 62, 64 of each of the second chassis slots 58 are in direct contact with the horizontal leg 46 of each of the heat-pipes 40 to maximize convective heat transfer from the horizontal leg 46 to the bottom wall 16. According to several aspects, to maximize conductive heat transfer, a heat conductive filler 65 such as solder or a heat conductive adhesive is inserted into the second chassis slots 58 after installation of the horizontal legs 46 to substantially fill the portion of the second chassis slots 58 not occupied by the horizontal legs 46. According to other aspects, the first and second walls 62, 64 of the second chassis slots 58 can be curved to substantially equal a radius of curvature corresponding to one-half of diameter “C”, thereby further maximizing the surface area of the horizontal legs 46 available for heat transfer to bottom wall 16.

With continuing reference to FIGS. 1 and 2, electronics chassis 10 further includes multiple L-shaped heat-pipes 66 which directly contact the first side wall 28 (removed from FIG. 2 for clarity) to aid cooling fins 26 in conductively transferring heat through first side wall 28. Heat-pipes 66 are substantially identical to heat-pipes 40 but are oppositely facing within cabinet 12. The vertical legs 42′ of heat-pipes 66 are positioned within third chassis slots 68 created in multiple heat transfer sleeves 50′ (only a portion of one heat transfer sleeve 50′ is shown in FIG. 2 for clarity) which are identical in design and function to heat transfer sleeves 50, but are directly connected to first side wall 28. According to several aspects, to maximize conductive heat transfer, the heat conductive material such as solder or heat conductive filler/adhesive 65 is also inserted into the third chassis slots 68 after installation of the vertical legs 42, 42′ to substantially fill the portion of the third chassis slots 68 not occupied by the vertical legs 42, 42′.

Each of the heat-pipes 66 also includes a horizontal leg 70 which is oppositely directed with respect to the horizontal legs 46 of heat pipes 40. Each horizontal leg 70 of the heat-pipes 66 is disposed in alternate ones of the multiple second chassis slots 58 created in bottom wall 16 such that each horizontal leg 46 is positioned proximate to at least one of the horizontal legs 70. A plurality of first mounting posts 72 are also connected to bottom wall 16 and extend upwardly from surface 60 proximate to first side wall 28. Similarly, a plurality of second mounting posts 74 are connected to bottom wall 16 and extend upwardly from surface 60 proximate to second side wall 34.

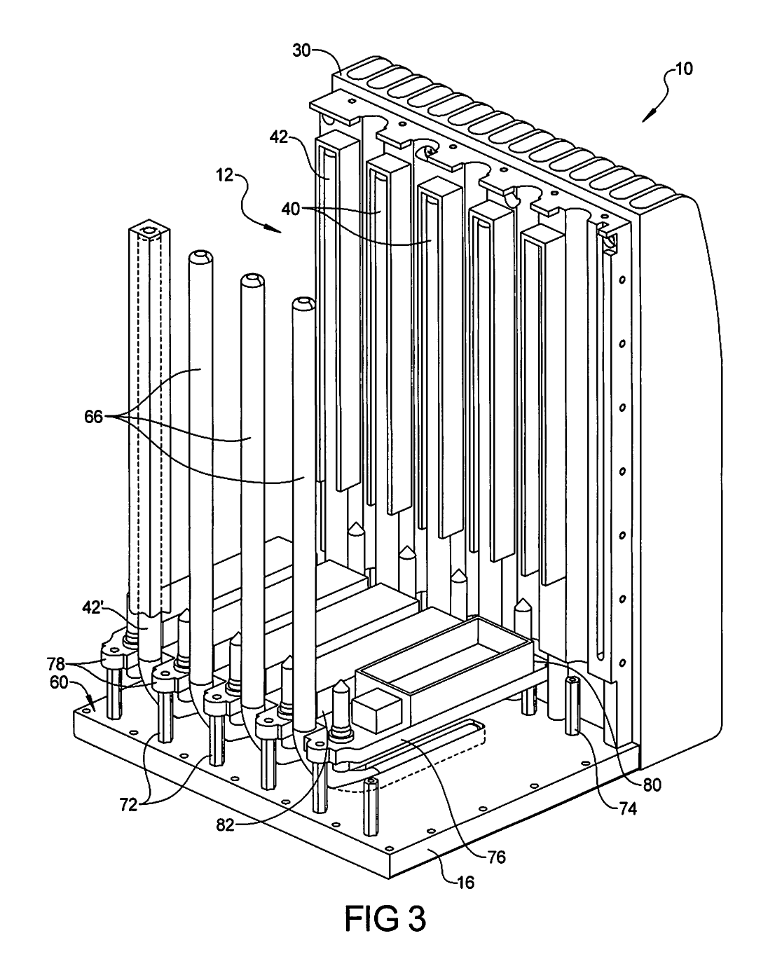

Referring to FIG. 3 and again to FIG. 2, after installation of the heat-pipes 40, 66 with their horizontal legs 46, 70 positioned in the second chassis slots 58, 58′ of bottom wall 16 and installation of the filler material 65, a backplane 76 is installed having multiple connecting members 78, the backplane slidably engaged with individual ones of the first mounting posts 72, and with multiple connecting members 80 slidably engaged with individual ones of the second mounting posts 74. Multiple electronic components 82 are connected to backplane 76 in an internal cavity of cabinet 12.

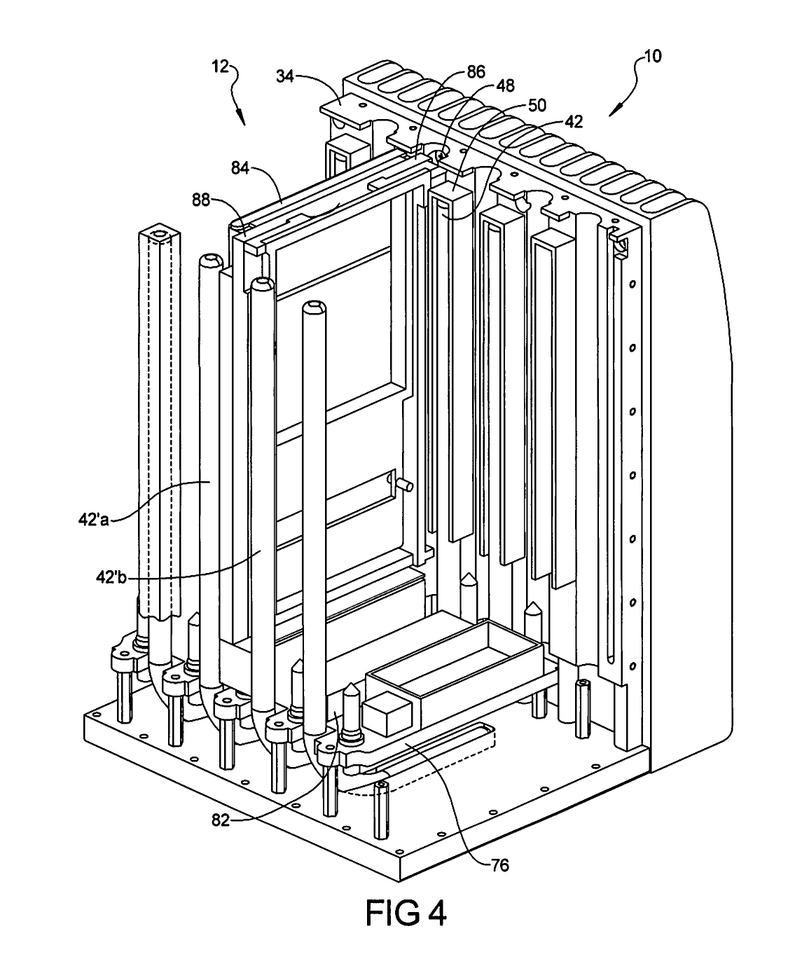

Referring to FIG. 4 and again to FIGS. 1-3, one of multiple component boards 84 such as a VPX board is shown in an installed position in cabinet 12. Each component board 84 includes a first engagement end 86 which is slidably and frictionally received in one of the component slots 48 of second side wall 34. Each component board 84 also includes an oppositely positioned second engagement end 88 which is slidably and frictionally received in one of the component slots 48′ of first end wall 28 (not shown for clarity). Each of the component boards 84 proximate to first engagement end 86 contacts two of the heat transfer sleeves 50. Similarly, but not shown for clarity, each of the component boards 84 proximate to second engagement end 88 contacts two of the heat transfer sleeves 50′. Successive vertical legs of the heat-pipes 40, 66, such as vertical legs 42′a, 42′b, are oppositely positioned about each of the component boards 84 in the slots of the heat transfer sleeves 50′ and extend for substantially an entire height of the component boards 84 to maximize heat transfer capability of the heat-pipes 40, 66 via the heat transfer sleeves 50, 50′. Each of the vertical legs 42, 42′ of the heat-pipes 40, 66 act to conductively and isothermally along the length of the heat producing component boards transfer heat generated by the component boards (which may each internally include their own heat-pipes connected to a heat frame) via the horizontal legs 46, 70 to the bottom wall 16.

Heat-pipes 40, 66 are embedded in the slots 58, 58′ of the bottom wall 16 of the chassis 10. Those skilled in the art will recognize that when embedded the heat-pipes 40, 66 can be positioned in direct contact with walls of the slots 58, 58′ to maximize conductive heat transfer to bottom wall 16, optionally also covered by the filler material 65 when in direct contact with the walls, or freely slidably received in the slots 58, 58′ with clearance to the walls and covered by the filler material 65 to maximize conductive heat transfer to bottom wall 16. Heat-pipes 40, 66 are similarly embedded in the side walls 28, 34 of the conduction cooled chassis 12 via the heat transfer sleeves 50, 50′ which provide a direct thermal path to the bottom wall 16 of the chassis 10. Heat-pipes 40, 66 can also be covered by the filler material 65 to maximize conductive heat transfer. This highly conductive thermal path provides improved thermal performance by transferring heat from the component boards 84 to the bottom wall 16, and also to the cooling fins where the heat is removed. The horizontal legs 46, 70 of L-shaped heat-pipes 40, 66 of the present disclosure are similarly embedded into the bottom wall 16 of the conduction cooled chassis 10. The exemplary implementation shown in FIGS. 2-4 is in a 3 U 3 slot VPX chassis. Each VPX slot 48 is cooled by two heat-pipes, which quickly and efficiently draw the heat from the card down to the bottom wall 16 of the chassis 10, which can also be interfaced to cold plate 38 to transfer the heat to the cold plate 38. It is noted the VPX chassis is provided as an exemplary embodiment and is not limiting, such that alternate chassis designs including VME and CPCI components can include the embedded cooling features of the present disclosure.

Referring again to FIG. 2, according to several aspects, the first and second heat-pipes 40, 66 are tubular shaped having diameter “C” which is substantially equal to a spacing “D” between the opposed walls 52, 54 of each heat transfer sleeve 50, 50′. According to further aspects, the first and second heat-pipes 40, 66 can be multiple different geometric shapes including a rectangular shape (one exemplary tube is shown with a rectangular shape) having a width “E” substantially equal to the spacing “D” between the opposed walls 52, 54 of the heat transfer sleeves 50, 50′. Other geometric shapes including but not limited to triangular, oval, flattened, and others can also be used. Heat-pipes 40, 66 can be of a thermally conductive material such as copper, having a thermally conductive liquid within, which is subject to vaporization/condensation to aid in thermal transfer from the vertical legs to the horizontal legs 42, 42′.

The present design offers several advantages, including that heat is quickly and efficiently moved from the cards/components to the bottom of the chassis, keeping high power devices, such as CPUs and memories of the electronic boards 84 within their operating limits. The embedded heat-pipes 40, 66 can either allow for an increased operating ambient temperature or higher power cards. Improvement of approximately 15-20%, either as a 15-20% higher operating temperature, or as a 15-20% increase in total system power is expected from the addition of directly contacted heat-pipes 40, 66.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A heat-pipe conduction cooling system for an electronics chassis, comprising:
a first cabinet portion having multiple first chassis slots;
a second cabinet portion having multiple second chassis slots;
a third cabinet portion having multiple third chassis slots;
multiple first heat-pipes having a first portion received in individual ones of the first chassis slots and a second portion received in individual ones of the second chassis slots; and
multiple second heat-pipes having a first portion received in individual ones of the third chassis slots and a second portion received in individual ones of the second chassis slots.

2. The heat-pipe conduction cooling system for an electronics chassis of claim 1, wherein the second cabinet portion is a cabinet bottom wall having the second chassis slots extending for less than a total depth of the bottom wall.

3. The heat-pipe conduction cooling system for an electronics chassis of claim 2, wherein the second portion of both the first and second heat-pipes defines a horizontal leg.

4. The heat-pipe conduction cooling system for an electronics chassis of claim 3, wherein a diameter of the horizontal leg of each of the first and second heat-pipes is substantially equal to a depth of the second chassis slots.

5. The heat-pipe conduction cooling system for an electronics chassis of claim 1, further including multiple heat transfer sleeves each connected to the first cabinet portion, wherein the first chassis slots are individually created between opposed first and second walls of each of the heat transfer sleeves of the first cabinet portion.

6. The heat-pipe conduction cooling system for an electronics chassis of claim 5, further including multiple heat transfer sleeves each connected to the third cabinet portion, wherein the third chassis slots are individually created between opposed first and second walls of each of the heat transfer sleeves of the third cabinet portion.

7. The heat-pipe conduction cooling system for an electronics chassis of claim 5, further including multiple component boards each having an engagement end contacting the first cabinet portion between and contacting two successive ones of the heat transfer sleeves.

8. The heat-pipe conduction cooling system for an electronics chassis of claim 1, wherein the first and third cabinet portions define parallel first and second cabinet walls.

9. The heat-pipe conduction cooling system for an electronics chassis of claim 1, further including a finned cooling member connected to the first and second cabinet walls.

10. The heat-pipe conduction cooling system for an electronics chassis of claim 1, wherein a cold plate is connected to the second cabinet portion oppositely facing with respect to the second chassis slots.

11. The heat-pipe conduction cooling system for an electronics chassis of claim 1, further including a heat conductive filler inserted into the first, second and third chassis slots after installation of the vertical legs and the horizontal legs acting to substantially fill portions of the first, second and third chassis slots not occupied by the heat-pipe vertical and horizontal legs.

12. A heat-pipe conduction cooling system for an electronics chassis, comprising:
a first cabinet portion defining a first chassis wall having multiple first chassis slots;
a second cabinet portion defining a bottom chassis wall having multiple second chassis slots;
a third cabinet portion defining a second chassis wall having multiple third chassis slots;
multiple first heat-pipes individually received in the first chassis slots and in first ones of the second chassis slots; and
multiple second heat-pipes individually received in the third chassis slots and in second ones of the second chassis slots.

13. The heat-pipe conduction cooling system for an electronics chassis of claim 12, wherein the first heat-pipes each include a vertical leg received in one of the first chassis slots and a horizontal leg received in one of the second chassis slots.

14. The heat-pipe conduction cooling system for an electronics chassis of claim 13, wherein the second heat-pipes each include a vertical leg received in one of the third chassis slots and a horizontal leg received in one of the second chassis slots.

15. The heat-pipe conduction cooling system for an electronics chassis of claim 12, further including multiple heat transfer sleeves each having opposed first and second walls, each heat transfer sleeve defining one of the first or third chassis slots.

16. The heat-pipe conduction cooling system for an electronics chassis of claim 15, wherein the first and second walls of the heat transfer sleeves are curved to substantially equal a radius of curvature corresponding to one-half of a diameter of the first and second heat-pipes.

17. The heat-pipe conduction cooling system for an electronics chassis of claim 15, further including multiple component boards having opposed engagement ends each contacting one of the first or second chassis walls, wherein each engagement end of the component boards is positioned between and contacts two of the heat transfer sleeves.

18. The heat-pipe conduction cooling system for an electronics chassis of claim 12, wherein successive first ones of the second chassis slots are separated by one of the second ones of the second chassis slots.

19. The heat-pipe conduction cooling system for an electronics chassis of claim 12, further including a cold plate in direct contact with the bottom chassis wall oppositely directed with respect to the second chassis slots.

20. A heat-pipe conduction cooling system for an electronics chassis, comprising:
a cabinet first wall having multiple heat transfer sleeves defining multiple first chassis slots;
a cabinet bottom wall having multiple second chassis slots; and
multiple first heat-pipes each having a vertical leg received in one of the first chassis slots and a horizontal leg received one of the second chassis slots.

21. The heat-pipe conduction cooling system for an electronics chassis of claim 20, further including a cabinet second wall having multiple heat transfer sleeves defining multiple third chassis slots.

22. The heat-pipe conduction cooling system for an electronics chassis of claim 21, further including multiple second heat-pipes each having a vertical leg received in one of the third chassis slots and a horizontal leg received one of the second chassis slots.

23. The heat-pipe conduction cooling system for an electronics chassis of claim 20, further including a cold plate in direct contact with the cabinet bottom wall completing a conduction heat path including the vertical leg of the first heat-pipes through the horizontal leg of the first heat-pipes and the cabinet bottom wall.

24. A heat-pipe conduction cooling system for an electronics chassis, comprising:
a cabinet first chassis wall having multiple heat transfer sleeves defining multiple first chassis slots;
a cabinet bottom chassis wall having multiple second chassis slots;
a cabinet second chassis wall having multiple heat transfer sleeves defining multiple third chassis slots;
multiple first heat-pipes each having a vertical leg received in one of the first chassis slots and a horizontal leg received one of the second chassis slots;
multiple second heat-pipes each having a vertical leg received in one of the third chassis slots and a horizontal leg received one of the second chassis slots; and
a cold plate in direct contact with the cabinet bottom chassis wall completing a conduction heat path including the vertical leg of the first and second heat-pipes through the horizontal leg of the first and second heat-pipes and the bottom chassis wall.

25. The heat-pipe conduction cooling system for an electronics chassis of claim 24, wherein the first and second heat-pipes are each L-shaped and include a bend joining the vertical leg to the horizontal leg.

26. The heat-pipe conduction cooling system for an electronics chassis of claim 24, wherein the first and second heat-pipes are tubular shaped having a diameter substantially equal to a spacing between opposed walls of each heat transfer sleeve.

27. The heat-pipe conduction cooling system for an electronics chassis of claim 24, wherein the first and second heat-pipes are rectangular shaped having a width substantially equal to a spacing between opposed walls of each heat transfer sleeve.
